(19) United States
(12) Patent Application Publication
(10) Pub. No.: US 2023/0172076 A1
(43) Pub. Date: Jun. 1, 2023

(54) QUANTUM CHIP AND CONSTRUCTION METHOD AND CONSTRUCTION APPARATUS THEREOF

(71) Applicant: BEIJING BAIDU NETCOM SCIENCE TECHNOLOGY CO., LTD., Beijing (CN)

(72) Inventors: Hanzhe XI, Beijing (CN); Zhengyi Cui, Beijing (CN); Lijing Jin, Beijing (CN)

(73) Assignee: BEIJING BAIDU NETCOM SCIENCE TECHNOLOGY CO., LTD., Beijing (CN)

(21) Appl. No.: 18/095,994

(22) Filed: Jan. 11, 2023

(30) Foreign Application Priority Data
Jan. 12, 2022 (CN) 202210031570.1

(51) Int. Cl. H10N 60/12; G06N 10/40; H10N 60/80

(52) U.S. Cl. CPC H10N 60/12; G06N 10/40; H10N 60/805

(57) ABSTRACT

A quantum chip is provided, includes: a first substrate and a second substrate arranged opposite to each other, wherein a plurality of qubits and a plurality of first controllers are arranged on a surface of the first substrate facing the second substrate, each of the plurality of qubits is coupled with at least one of the plurality of first controllers, and a plurality of control signal transmission parts are arranged on a surface of the second substrate facing the first substrate; and a plurality of connecting pieces, connected between the first substrate and the second substrate, and configured to connect the plurality of first controllers to the plurality of control signal transmission parts in a one-to-one corresponding mode.

### CROSS REFERENCE TO RELATED APPLICATIONS

The present application claims priority to Chinese Patent Application No. 202210031570.1 filed on Jan. 12, 2022, the content of which is hereby incorporated by reference in its entirety for all purposes.

### TECHNICAL FIELD

The present disclosure relates to the field of quantum computing, in particular to the field of quantum chip design, and specifically relates to a quantum chip and a construction method and construction apparatus thereof.

### BACKGROUND

Since the concept of quantum computing was first proposed, many scientists have begun to explore in this field. At present, researchers have implemented a basic unit of quantum computing, qubits, on several physical platforms. The qubits include superconducting circuits, ion traps, nuclear magnetic resonance, diamond color centers, etc. Benefiting from advantages of long decoherence time, easy manipulation, and easy preparation, the superconducting circuits have become a physical realization technical route that has attracted much attention. On the road to fault-tolerant quantum computing, technologies such as quantum error-correcting codes are usually required to be applied, that is, many physical qubits are used to realize a logical qubit. In other words, developing a quantum computer having a fault-tolerant capability requires a considerable number of physical qubits. Therefore, expanding the number of the qubits has become a matter of great concern to the industry.

### SUMMARY

The present disclosure provides a quantum chip and a construction method and construction apparatus thereof.

According to a first aspect of the present disclosure, a quantum chip is provided and includes: a first substrate and a second substrate arranged opposite to each other, wherein a plurality of qubits and a plurality of first controllers are arranged on a surface of the first substrate facing the second substrate, each of the plurality of qubits is coupled with at least one of the plurality of first controllers, and a plurality of control signal transmission parts are arranged on a surface of the second substrate facing the first substrate; and a plurality of connecting pieces, connected between the first substrate and the second substrate, and configured to connect the plurality of first controllers to the plurality of control signal transmission parts in a one-to-one corresponding mode.

According to a second aspect of the present disclosure, a construction method of a quantum chip is provided and includes: arranging a first substrate and a second substrate opposite to each other; arranging a plurality of qubits and a plurality of first controllers on a surface of the first substrate facing the second substrate, each of the plurality of qubits is coupled with at least one of the plurality of first controllers; arranging a plurality of control signal transmission parts on a surface of the second substrate facing the first substrate; and arranging a plurality of connecting pieces between the first substrate and the second substrate, such that the connecting pieces connect the plurality of first controllers to the plurality of control signal transmission parts in a one-to-one corresponding mode.

According to a fourth aspect of the present disclosure, an electronic device is provided and includes: a memory storing one or more programs configured to be executed by one or more processors, the one or more programs including instructions for causing the electronic device to perform operations comprising: arranging a first substrate and a second substrate opposite to each other; arranging a plurality of qubits and a plurality of first controllers on a surface of the first substrate facing the second substrate, each of the plurality of qubits is coupled with at least one of the plurality of first controllers; arranging a plurality of control signal transmission parts on a surface of the second substrate facing the first substrate; and arranging a plurality of connecting pieces between the first substrate and the second substrate, such that the connecting pieces connect the plurality of first controllers to the plurality of control signal transmission parts in a one-to-one corresponding mode.

It should be understood that the content described in this section is not intended to identify key or critical features of embodiments of the present disclosure, nor is it intended to limit the scope of the present disclosure. Other features of the present disclosure will become readily understood from the following description.

### BRIEF DESCRIPTION OF THE DRAWINGS

The accompanying drawings are used to facilitate understanding of the present solution, and do not constitute a limitation to the present disclosure.

FIG. 1 is a schematic structural diagram illustrating a quantum chip according to an embodiment of the present disclosure.

FIG. 2 is a schematic partial structural diagram illustrating a quantum chip according to an embodiment of the present disclosure.

FIG. 3 is a schematic partial structural diagram illustrating a quantum chip according to another embodiment of the present disclosure.

FIG. 4 is a schematic partial structural diagram illustrating a quantum chip according to further another embodiment of the present disclosure.

FIG. 5 is a schematic structural diagram illustrating a first controller according to an embodiment of the present disclosure.

FIG. 6 is a schematic structural diagram illustrating a first controller according to another embodiment of the present disclosure.

FIG. 7 is a schematic structural diagram illustrating a first controller according to further another embodiment of the present disclosure.

FIG. 8 is a schematic structural diagram illustrating a signal transmission part according to an embodiment of the present disclosure.

FIG. 9 is a schematic structural diagram illustrating a coupler according to an embodiment of the present disclosure.

FIG. 10 is a schematic partial structural diagram illustrating a quantum chip according to yet another embodiment of the present disclosure.

FIG. 11 is a schematic partial structural diagram illustrating a quantum chip according to yet another embodiment of the present disclosure.

FIG. 12 is a schematic flow chart of a construction method illustrating a quantum chip according to an embodiment of the present disclosure.

FIG. 13 is a schematic flow chart of a construction method illustrating a quantum chip according to another embodiment of the present disclosure.

FIG. 14 is a schematic diagram of a construction apparatus illustrating a quantum chip according to an embodiment of the present disclosure.

FIG. 15 is a block diagram illustrating an electronic device for implementing a construction method of a quantum chip according to an embodiment of the present disclosure.

### DESCRIPTION OF REFERENCE NUMERALS

100, first substrate; 101, first superconducting metal layer;

110, qubit; 120, first controller; 120a, magnetic flux controller; 120b, reading controller; 120c, microwave controller; 111, first capacitor arm of qubit; 111a, 111b, 111c and 111d, four arm ends of first capacitor arm; 112, second capacitor arm of qubit; 112a, 112b and 112c, three second capacitor arms; 130, coupler; 121, coupling port of first controller; 121a, coupling port of magnetic flux controller in first controller; 121b, coupling port of reading controller in first controller; 122, connecting plate of first controller; 122a, connecting plate of magnetic flux controller in first controller; 122b, connecting plate of reading controller in first controller; 113, adjustable capacitor arm; 140, Josephson junction on second capacitor arm; 123a, magnetic flux control circuit; 150, second controller; 130a, rectangular capacitor of coupler; 130b, Josephson junction of rectangular capacitor;

200, second substrate; 201, second superconducting metal layer;

210, control signal transmission part; 211, connecting port; 212, transmission line; 213, pin; 210a, magnetic flux control signal transmission part; 210b, microwave control signal transmission part; 210c, reading control signal transmission part; 214, reading cavity; 215, reading signal line; and

300, connecting piece.

### DETAILED DESCRIPTION

Exemplary embodiments of the present disclosure are described below with reference to the accompanying drawings, which include various details of the embodiments of the present disclosure to facilitate understanding and should be considered as exemplary only. Accordingly, those of ordinary skill in the art should realize that various changes and modifications can be made to the embodiments described herein without departing from the scope of the present disclosure. Also, descriptions of well-known functions and constructions are omitted from the following description for clarity and conciseness.

The term “and/or” herein is only an association relationship describing associated objects, indicating that there may be three kinds of relationships. For example, A and/or B may mean that there are three cases: A exists alone, A and B exist at the same time, and B exists alone. The term “at least one” herein refers to any combination of any one of a plurality or at least two of a plurality, for example, including at least one of A, B, and C, may represent including any one or more elements selected from a set of A, B, and C. The terms “first” and “second” herein refer to and distinguish between a plurality of similar technical terms, and do not mean to limit the order, or to limit the quantity to be only two. For example, a first feature and a second feature mean that there are two types/two features, there may be one or more first features, and there may be one or more second features.

In addition, in order to better illustrate the present application, numerous specific details are given in specific embodiments below. It should be understood by those skilled in the art that the present application may be practiced without certain specific details. In some instances, methods, means, components and circuits well known to those skilled in the art are not described in detail so as not to obscure the subject matter of the present application.

In a process of designing quantum chips, in order to further improve computing performance of a quantum chip, it is necessary to place as many qubits as possible in chip regions of the same size. However, limited by the existing processing technology, the design difficulty increases exponentially every time a qubit is added, so random expansion of the qubits on the chip cannot be realized, which also directly leads to a low utilization rate of a unit area of the chip.

From the perspective of quantum chip design, there are several technical solutions in the industry to place as many qubits as possible.

The first solution is to modularize the quantum chips (develop standardized modules). This method standardizes the design of quantum chips, reserves connection ports on each chip, and then uses superconducting metal to capacitively couple these standard chips, so as to connect each chip to realize the purpose of expanding the number of the qubits.

However, disadvantages of the above-mentioned “quantum chip modularized design” solution include: this solution wastes a space of the chip to a certain extent. Since one qubit can only couple to qubits on another chip, connectivity between the qubits is inhibited. Here, due to a low space utilization rate, a size of the chip is excessively large, and an integration degree is not high. Especially when the qubits are scaled, higher requirements are placed on the space for placing the quantum chips.

The second solution is to place the qubits as well as control line ports and resonant cavities on two different substrates respectively, and is also known as a “non-planar coupling” solution. According to the solution, the qubits and the resonant cavities are placed separately on two chip substrates (such as parallel upper and lower substrate plates), so a capacitor is formed between devices on the two substrates, i.e. superconducting metal plates on the substrates, and a qubit layer is coupled to a resonant cavity level by a method of non-planar capacitive coupling, thus realizing energy exchange. Such a design prevents the expansion of bits in the qubit layer from being influenced by the resonant cavities, and a symmetrical structure of cross-shaped qubits is also very suitable for expansion in multiple directions on the quantum chip. In addition, such a non-planar structure reduces crosstalk between the qubits and the resonant cavities, and improves stability of the chip.

However, the above-mentioned solution of “non-planar coupling of qubits and resonant cavities” has the following disadvantages: first, design difficulty of non-planar coupling is great; and second, a coupling strength between the qubits and the resonant cavities is related to spacing between the two substrates, which raises relatively high requirements for a processing technology. Particularly, in an assembling process, process errors are prone to causing deviation between a practical coupling strength and a design value.

The third solution is also to place the qubits and the resonant cavities on two different substrates separately, and then connect the qubit layer and the resonant cavity layer by using vias (holes are drilled in a silicon substrate, and then are filled with metal or superconducting metal to stack a plurality of chips, which plays an important role in three-dimensional chip packaging). The through-silicon vias can be used to shield an electric field between the qubits and the resonant cavities, thereby reducing crosstalk. On the other hand, the quantum chip is controlled by full microwave, so the qubits are all fixed frequency Transmon, and there is no magnetic flux crosstalk. In addition, heavy hexagonal coding (a surface coding method consisting of control qubits and ordinary qubits, and using a matching algorithm to correct errors in qubits) is used to place and connect the qubits, so as to build a quantum computer with error correction capabilities.

However, the solution that “qubits and resonant cavities are coupled through through-silicon vias” has the following disadvantages: the solution completely uses microwave control chips, so the corresponding qubits are superconducting qubits with a fixed frequency, which raises relatively high requirements for precision of a processing technology. On the other hand, when expanding the number of the qubits on a chip, it is not only necessary to consider the frequency of a single qubit, but also necessary to consider the conditions of surrounding qubits so as to prevent frequency collisions. Therefore, chip initialization in this solution (referring to a parameter design of geometric dimensions of each component on the chip) is relatively complicated.

The fourth solution is to place the qubits and the resonant cavities on the same chip in a coplanar manner, and couple the resonant cavities and the qubits by coplanar capacitive coupling (metal plates of capacitors are on the same substrate). Relatively low requirements are raised for a processing technology, and a preparation process is relatively simple.

However, the solution of “coplanar coupling of qubits and resonant cavities” has the following disadvantages: this solution can only achieve expansion in one-dimensional or two-dimensional plane directions, and the expandability is relatively limited. At the same time, because control lines and the qubits are in the same plane in the case of coplanar coupling, the qubits are often affected by a magnetic field caused by current passing through the control lines, thereby affecting the performance of coplanarly coupled quantum chips.

In a design process of the quantum chips (especially for superconducting quantum chips), geometric sizes of elements and placement locations between the elements are designed according to the required feature parameters of the quantum chips (such as a qubit frequency, a detuning strength, a reading resonant cavity frequency, a coupling strength between different devices, etc.) or electrical parameters (such as self-capacitance of the qubits, equivalent inductance of Josephson junctions, mutual capacitance between different devices, etc.), and quantitative expansion is then performed, which is a very complex problem and has increasing complexity according to the number of the qubits. In the present disclosure, a 3D (3 Dimensional) superconducting quantum chip architecture that is easy to initialize (i.e., geometric sizes and placement locations of elements are determined according to parameter requirements) and easy to expand is shown.

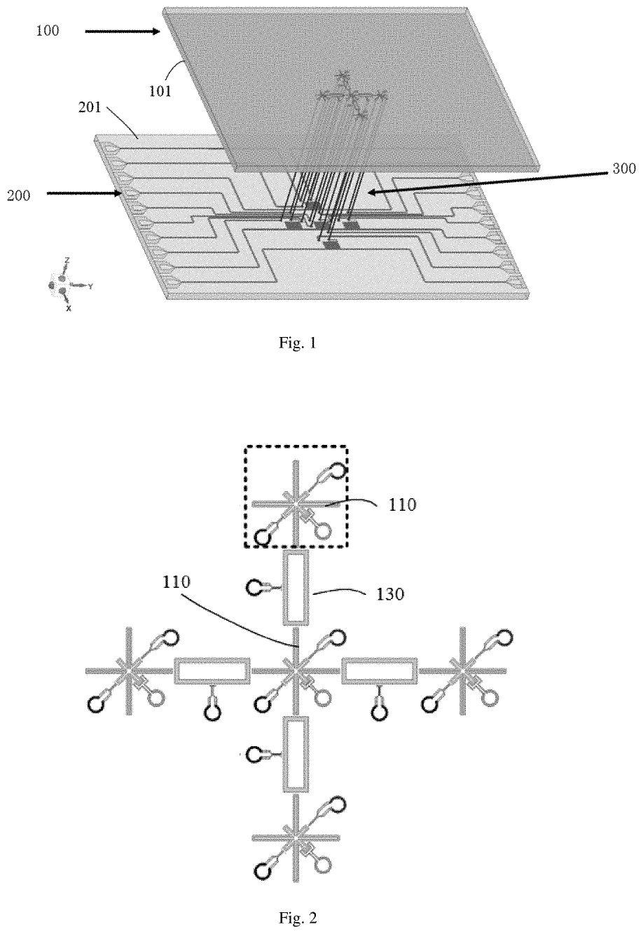

According to an embodiment of the present disclosure, a quantum chip is provided (the quantum chip shown by the present disclosure contains a plurality of layers, so it is also called a 3D quantum chip or a 3D superconducting quantum chip. It should be noted that superconducting quantum chips are one kind of quantum chips, and a technical solution of the present disclosure is mainly based on a superconducting quantum chip). FIG. 1 is a schematic structural diagram of a quantum chip according to an embodiment of the present disclosure. As shown in FIG. 1, the quantum chip specifically includes a first substrate 100 and a second substrate 200 arranged opposite to each other, and a plurality of connecting pieces 300.

In an example, the first substrate 100 and the second substrate 200 usually adopt silicon or sapphire. A first superconducting metal layer 101 is arranged on a surface of the first substrate 100 facing the second substrate 200 and functionally serves as a core computing layer of the quantum chip. A second superconducting metal layer 201 is arranged on a surface of the second substrate 200 facing the first substrate 100 and functionally serves as a wiring layer of the core computing layer of the quantum chip. The first superconducting metal layer 101 and the second superconducting metal layer 201 are usually aluminum or other superconducting metals.

The first substrate 100 and the second substrate 200 may be connected using a flip-chip bonding technology in traditional electronic technologies. The second substrate 200 is located at a bottom layer, and the second superconducting metal layer 201 faces upwards (in a forward direction of a Z axis; and the first substrate 100 is located at a top layer, and the first superconducting metal layer 101 faces downwards (in a negative direction of the Z axis). That is, the superconducting metal layers of the first substrate 100 and the second substrate 200 are arranged opposite to each other.

The first superconducting metal layer 101 and the second superconducting metal layer 201 are connected to each other through the connecting pieces 300 (also known as superconducting metal posts, and usually made of a material of indium), thus realizing control and state reading of the quantum chip.

It should be noted that, in order to better show an entire structure in FIG. 1, the connecting pieces 300 are subject to extension treatment. In a practical design, spacing between the first substrate 100 and the second substrate 200 may be arranged to be very small, but no limitation is made to specific spacing.

Further, a plurality of sets of coupled qubits and first controllers are arranged on the surface of the first substrate 100 facing the second substrate 200. That is, the first superconducting metal layer 101 includes the plurality of sets of coupled qubits and first controllers. Specifically, FIG. 2 illustrates the plurality of sets of coupled qubits and first controllers. A part circled by a dotted line is a set of coupled qubits and first controllers.

Exemplarily, FIG. 2 shows a minimum cross-shaped unit structure of arrangement of the qubits in a two-dimensional array, which includes 5 sets of coupled qubits and first controllers. One set of the coupled qubits and first controllers includes one qubit and one or a plurality of first controllers.

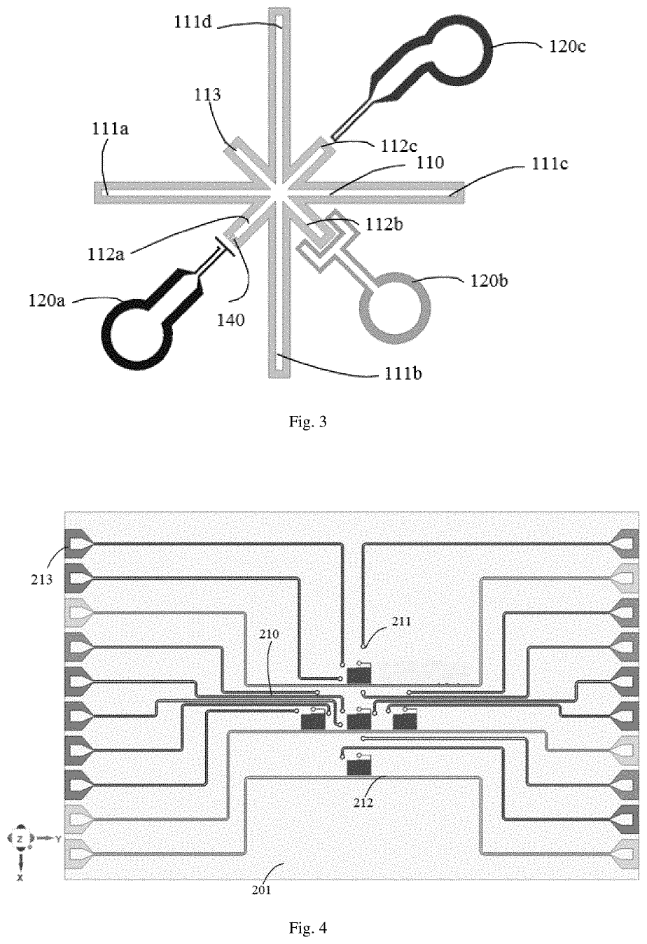

FIG. 3 shows a set of coupled qubits and first controllers, including one qubit 110 and three first controllers 120a, 120b and 120c that are coupled to each other. The qubit 110 may be a Union Jack type qubit as shown in FIG. 3, or may be a qubit of other structures, which is not limited here. In addition, the qubit 110 shown in FIG. 3 includes a right cross-shaped first capacitor arm 111 (also called a long arm). The first capacitor arm 111 has four arm ends, respectively 111a, 111b, 111c and 111d, which are used to be coplanarly coupled to the adjacent qubit 110.

A plurality of control signal transmission parts 210 are arranged on the surface of the second substrate 200 facing the first substrate 100. That is, the second superconducting metal layer 201 includes the plurality of control signal transmission parts 210. Specifically, as shown in FIG. 4, each control signal transmission part 210 includes a connecting port 211, a transmission line 212 and a pin 213. The pin is arranged at an edge of the quantum chip and is used to connect to a transmission component outside the quantum chip.

As mentioned before, the quantum chip further includes the plurality of connecting pieces 300 which are connected between the first substrate 100 and the second substrate 200. The connecting pieces are configured to connect the plurality of first controllers 120 to the plurality of control signal transmission parts 210 in a one-to-one corresponding mode.

Compared to architectures of other quantum chips in the industry, the quantum chip of the present disclosure places the qubits 110 and the first controllers 120 on the same layer, which lowers a difficulty of parameter initialization of devices on the core computing layer and a difficulty of chip processing. Compared to non-planar coupling in the prior art, a final coupling strength will not be affected by placement errors of two planes. Further, the quantum chip of the present disclosure further places the qubits 110 and the signal transmission parts 210 on different substrates. To add one qubit 110, one can just expand the matched control signal transmission parts 210 on different substrates, so a design difficulty is lowered, and expandability of the qubits 110 on the quantum chip is improved.

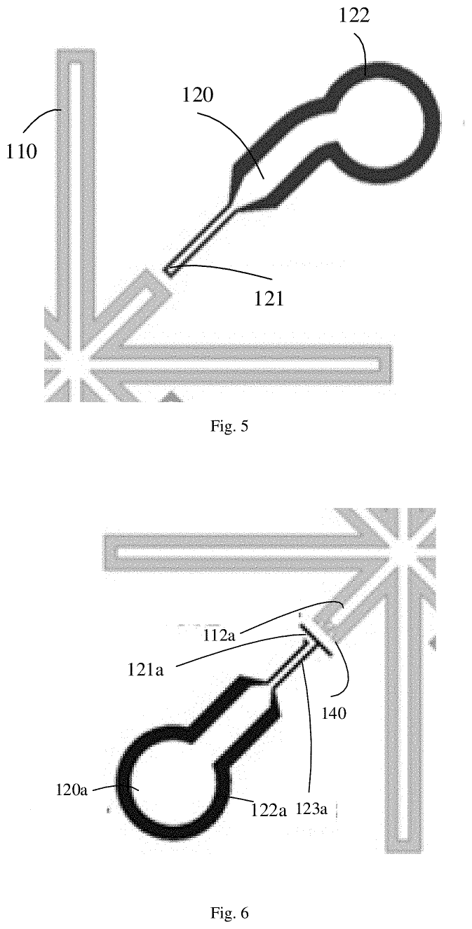

As shown in FIG. 5, each first controller 120 may include a coupling port 121 and a connecting plate 122. The coupling port 121 is coupled to the qubit 110 corresponding to the first control 120, and the connecting plate 122 is connected to the connecting piece 300 corresponding to the first controller 120. In one example, the connecting plate 122 is round and is configured to be connected to the cylindrical connecting piece 300, and the coupling port 121 is coplanarly connected to the connecting plate 122. In the quantum chip adopting the above structure, the qubits 110 may be coplanarly coupled to the corresponding first controllers 120, the coplanar coupling structure can not only reduce a difficulty of chip processing technology, but also enable the first controllers 120 to flexibly adjust distances from the qubits 110, so relevant feature values are changed.

As shown in FIG. 3, the plurality of first controllers 120 may include at least one of a magnetic flux controller 120a, a microwave controller 120c and a reading controller 120b. Three first controllers 120a, 120b and 120c are coplanarly coupled to three short arms (also called second capacitor arms) 112a, 112b and 112c of the qubit 110, respectively. A Josephson junction 140 is arranged on a tail end of the short arm 112a coupled to the magnetic flux controller 120a. Through the above structure, the qubit specially uses the short arms 112a, 112b and 112c for coupling with the first controllers 120, which will not affect connection with the adjacent qubits and may connect as many first controllers 120 as possible.

In one example, the plurality of first controllers 120 include the magnetic flux controllers 120a, and each magnetic flux controller 120a further includes a magnetic flux control circuit 123a. As shown in FIG. 6, the magnetic flux control circuit 123a is arranged between a coupling port 121a and a connecting plate 122a of the magnetic flux controller 120a. The magnetic flux control circuit 123a is configured to adjust a frequency of the corresponding qubit 110. By adjusting a current in the magnetic flux control circuit 123a, a magnetic field generated thereby may be changed, thus affecting the adjacent Josephson junctions 140 and further changing the frequency of the entire qubit 110. By using the above structure, the current of the magnetic flux controller 120a may be flexibly adjusted, so that the frequency of the qubit 110 accords with a target value, which lays a foundation for precise design of the quantum chip.

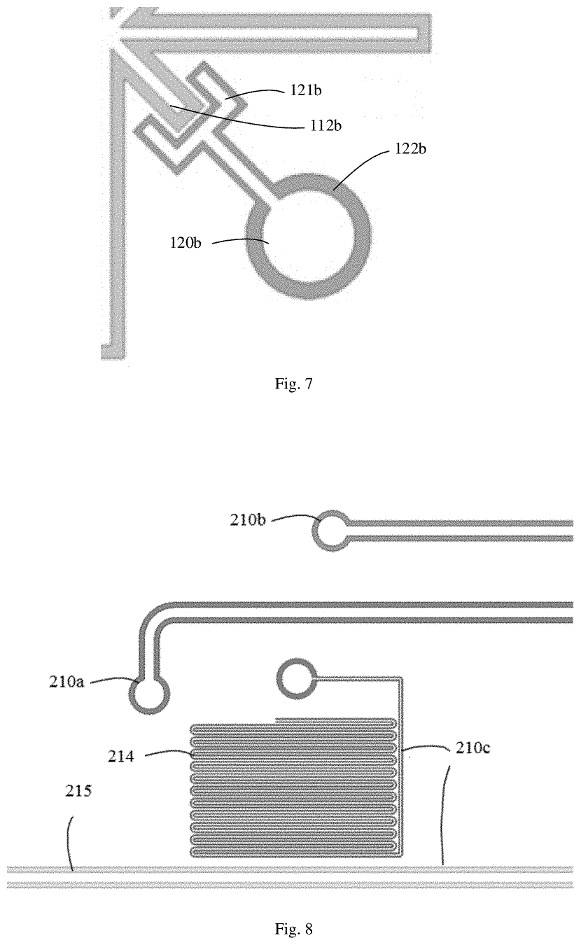

As shown in FIG. 7, the plurality of first controllers 120 include the reading controllers 120b, and the coupling ports 121b of the reading controllers 120b are interdigital capacitors. The coupling ports 121b are connected to the connecting plates 122b of the reading controllers 120b and are configured to read signals of the qubits 110. By using the architecture, the interdigital capacitors may be connected to the second capacitor arms 112b more closely, so the coupling strength is stronger.

In one example, as shown in FIG. 8, the plurality of control signal transmission parts 210 include magnetic flux control signal transmission parts 210a, microwave control signal transmission parts 210b and reading control signal transmission parts 210c. The magnetic flux control signal transmission parts 210a obtain relevant control signals of the magnetic flux controllers 120a in the first substrate 100 through connection with the connecting pieces 300; the microwave control signal transmission parts 210b obtain relevant control signals of the microwave controllers 120c in the first substrate 100 through connection with the connecting pieces 300; and the reading control signal transmission parts 210c obtain relevant control signals of the reading controllers 120b in the first substrate 100. By using the above architecture, the magnetic flux control signal transmission parts 210a, the microwave control signal transmission parts 210b and the reading control signal transmission parts 210c are arranged on the second substrate 200 for the magnetic flux controllers 120a, the microwave controllers 120c and the reading controllers 120b respectively and are configured to transmit corresponding control signals. Because the relatively independent signal transmission parts are adopted, mutual interference in a signal transmission process is avoided, and it is ensured that received signals are accurate.

In one example, the plurality of control signal transmission parts 210 include the reading control signal transmission parts 211 and 212 corresponding to the reading controllers 120b. As shown in FIG. 8, each reading control signal transmission part may include a reading cavity 214 and a reading signal line 215, and the reading cavity 214 is connected to the connecting plate 122b of the corresponding reading controller 120b. The reading signal lines 215 adopt a multiplexing manner, that is, one reading signal line 215 is coupled to reading cavities 214 of different frequencies corresponding to different qubits 110. On the entire quantum chip, usually one reading signal line 215 is used to be coupled to a plurality of reading cavities 214 corresponding to a plurality of qubits 110 in one row or one column. By using the above architecture, through the multiplexing manner, the quantity of the reading signal lines 215 may be reduced, space of the second substrate 200 and the quantity of external lines (a room temperature control system) may be saved.

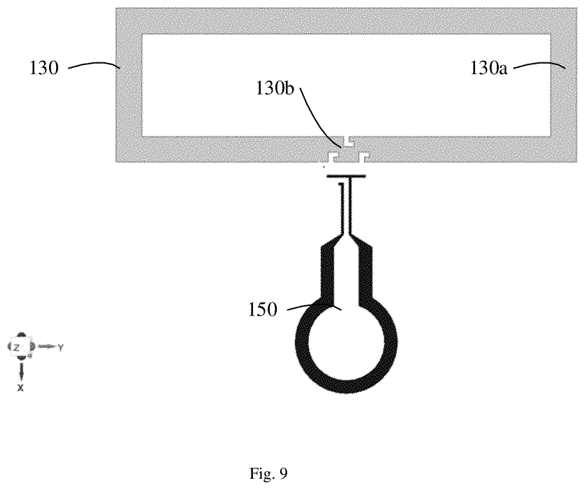

In one example, the above quantum chip further includes couplers 130. As shown in FIG. 2, the couplers 130 are arranged on the surface of the first substrate 100 facing the second substrate 200 and are located between the adjacent qubits 110. The quantum chip further includes at least one second controller 150. As shown in FIG. 9, the second controllers 150 are arranged in one-to-one correspondence to at least one coupler 130, and the second controller 150 are configured to adjust a frequency of the corresponding couplers 130. By using the above architecture, the frequency of the couplers 130 can be flexibly adjusted, so coupling of adjacent qubits is realized.

In one example, as shown in FIG. 9, each coupler 130 mentioned includes a rectangular capacitor 130a, and a Josephson junction 130b arranged on the rectangular capacitor 130a. The couplers 130 are coupled to the first capacitor arms 111 of the qubits 110 through two short edges of each rectangular capacitor 130a, so two adjacent qubits 110 are connected. By using the above architecture, the rectangular capacitors 130a are connected to the second controllers 150 through the Josephson junctions 130b, so a closer connection is realized.

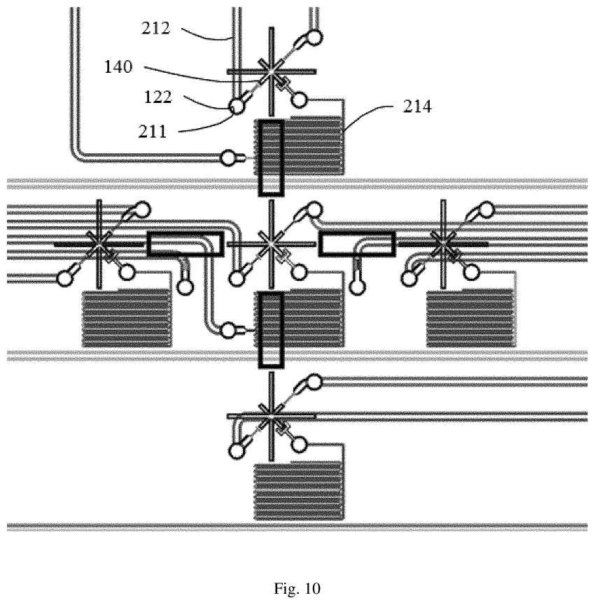

In one example, FIG. 10 provides a top view of a mask after the first substrate 100 and the second substrate 200 are assembled. The mask is used to project a lithography pattern on photoresist in a lithography process of chip production. Therefore, the mask may reflect structures of the first substrate 100 and the second substrate 200. It can be seen that the connection plates 122 of the first controllers 120 on the first substrate 100 are vertically corresponding to the connecting ports 211 of the second substrate 200 and are connected with external signal lines through the transmission lines 212 and pins 213 (not shown in FIG. 10). In order to reduce an influence of the reading cavities 214 on the qubits 110, the reading cavities 214 are placed at locations that do not overlap with a vertical direction of the Josephson junctions 140 of the qubits 110. Meanwhile, in order to facilitate wiring processing, the locations of the connecting plate 122 may be flexibly adjusted without affecting the coupling design between the qubits on the first substrate 100.

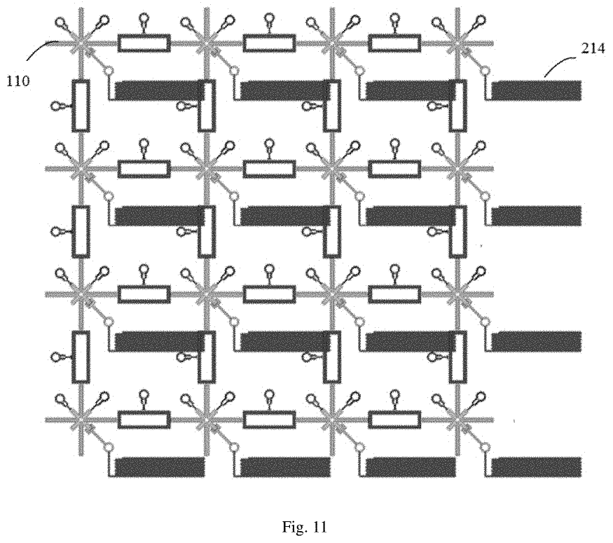

In one example, the quantum chip of the present disclosure has a very good expandability. As shown in FIG. 11, because the qubits 110 designed in a Union Jack structure are adopted, a basic size of one qubit 110 may be designed according to a target frequency range of the qubits in practically requirements. In order to adjust sizes of the capacitors of the qubits 110, adjustable capacitor arms 113 may be adjusted to complete a design. In this way, sizes of the first capacitor arms 111 in X/Y axis directions of the entire qubits 110 are maintained unchanged, so a space occupied by the entire qubits 110 is unchanged, and a two-dimensional array structure may be obtained merely through expansion in the X/Y axis direction, as shown in FIG. 11.

Similarly, for the reading cavity 214 corresponding to each qubit 110, a benchmark length may be determined based on a target frequency range of the reading cavity 214, and then fine adjustment in length is made to the frequency of each reading cavity 214. In this way, an overall occupied space of each reading cavity 214 is determined, and the reading cavities merely need to be placed corresponding to each qubit 110. According to a schematic diagram of the quantum chip with 4*4 qubits 110 as shown in FIG. 11 (the figure is a schematic diagram and does not include signal reading lines and wiring), after initialization of a part of qubits 110, the design of the entire quantum chip may be completed merely through expansion in the X/Y axis directions.

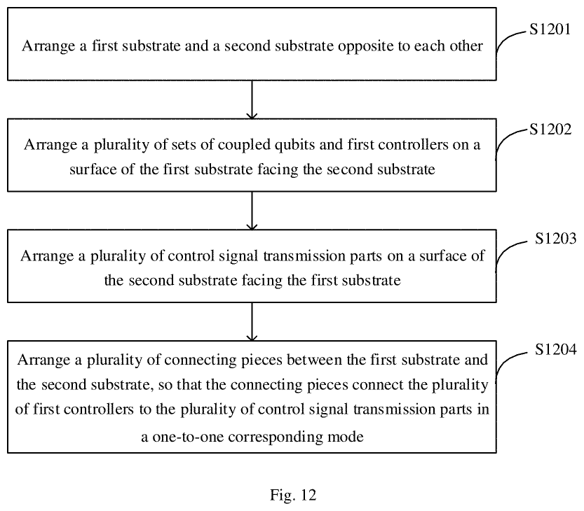

According to an embodiment of the present disclosure, a construction method of a quantum chip is provided. FIG. 12 is a schematic flow chart of the construction method of the quantum chip according to an embodiment of the present disclosure, specifically including:

S1201: a first substrate and a second substrate are arranged opposite to each other;

S1202: a plurality of sets of coupled qubits and first controllers are arranged on a surface of the first substrate facing the second substrate;

S1203: a plurality of control signal transmission parts are arranged on a surface of the second substrate facing the first substrate; and

S1204: a plurality of connecting pieces are arranged between the first substrate and the second substrate, so that the connecting pieces connect the plurality of first controllers to the plurality of control signal transmission parts in a one-to-one corresponding mode.

In one example, the opposite first substrate and second substrate are arranged first, and then intrinsic parameters such as target frequencies of the qubits and the first controllers are respectively input, so as to calculate sizes of elements such as the qubits and couplers in the first substrate; locations of the elements on the first substrate are determined according to coupling demands; and sizes and locations of the control signal transmission parts, especially resonant cavities, on the second substrate are determined based on the locations of the elements in the first substrate, then locations of pins and connecting ports in the signal transmission parts are determined, and finally wiring is performed according to the locations of the pins, the locations of the resonant cavities, and the locations of the connecting ports. After wiring, the connecting pieces are arranged according to the first substrate and the second substrate. Theoretically, heights of the connecting pieces are not limited, and in addition to transmitting data, the connecting pieces further fulfill a function of mechanically supporting the two substrates.

In one example, in a process of initialization of parameter design of the first substrate, specific sizes of capacitors of the qubits and rectangular capacitors may also be designed according to required frequencies of the qubits and couplers, and the parts of the coupling ports are designed according to magnitudes of coupling strengths of the couplers. Compared to design manners of non-planar coupling in other solutions in the industry, control and reading of the qubits in the present solution adopt a manner of coplanar coupling, so a design difficulty is low, and an efficiency of designing the entire quantum chip is improved.

By constructing the quantum chip using the above-mentioned solution, compared to other quantum chip design solutions in the industry, a difficulty on a design level is low, and at the same time, the good expandability is further maintained, which is conducive to automatic large-scale design of superconducting quantum chips. Specifically speaking, the solution of the present disclosure has obvious advantages as follows.

First, the manner of coplanar coupling is adopted in both the design of the sizes of the elements on the first substrate as well as coupling between different elements. Compared to the manner of non-planar coupling adopted in other solutions in the industry, a coplanar coupling design is smaller in design difficulty, and a parameter initialization process of the chip may be performed more easily.

Second, unlike single-layer chips and connection and expansion between different single-layer chips, the solution adopts a manner of separating the qubits and the control signal transmission parts which are arranged on the first substrate and the second substrate respectively. The quantity of qubits may be expanded on the first substrate according to a model of a two-dimensional array, and it is merely necessary to add the corresponding signal transmission parts to the second substrate. The expandability of the chip is stronger, and an area utilization rate is larger.

Third, in order to prevent the reading cavities in the control signal transmission parts from exerting an influence on the Josephson junctions in the qubits in the first substrate, the reading cavities are placed at positions that are heteroplanar to and do not overlap with the Josephson junctions, so possible crosstalk between different elements is reduced.

Fourth, because the Union Jack structure of the qubits is adopted, the coupling between the qubits and the controllers is more flexible, the locations of the controllers may be adjusted according to a wiring difficulty of a practical wire drawing layer, so the wiring difficulty of the second substrate is reduced, and the design difficulty of the chip is further lowered.

Fifth, the qubits of the Union Jack structure have high symmetry, so they are easily expanded on the two-dimensional plane. On the other hand, the intrinsic frequency of the qubits of the Union Jack structure may be realized through fine adjustment to a length of one capacitor arm, so sizes of main bodies of the qubits are not changed in an adjustment process, and a situation that locational transition is not caused in an expansion process to affect a layout of the entire chip can be ensured.

In one example, the construction method of the quantum chip further includes:

at least one coupler is arranged on the surface of the first substrate facing the second substrate, and the coupler is caused to be located between the adjacent qubits. In one example, the coupler includes a rectangular capacitor, and the coupler is configured to indirectly connect two adjacent qubits. Via connection through the coupler, connection flexibility between the qubits may be increased, and locations of the qubits may be changed through adjusting the coupler, so a layout difficulty of elements on the chip is lowered.

In one example, in the construction method of the quantum chip, arranging the plurality of qubits, the plurality of first controllers and the at least one coupler on the surface of the first substrate facing the second substrate includes:

relative distances among the plurality of qubits, the coupler and the plurality of first controllers are determined according to a target feature value; and arrangement locations of the plurality of qubits, the coupler and the plurality of first controllers on the first substrate are determined according to sizes of the plurality of qubits, the coupler and the plurality of first controllers as well as the relative distances. Specifically, the target feature value may include mutual capacitors between the elements, and then the distances among the qubits, the coupler and the plurality of first controllers are determined. Sizes of the qubits, the coupler and the plurality of first controllers may be obtained directly, or may be obtained through calculation according to some intrinsic parameters, which is not limited in the present application. After obtaining the sizes of the qubits, the coupler and the plurality of first controllers, the locations of these elements on the first substrate are determined in combination with the relative distances calculated previously. By adopting the above solution, the locations of the elements including the qubits, the coupler and the plurality of first controllers on the first substrate may be determined in a high-efficiency and accurate way. In addition, compared to a non-planar arrangement, the above elements are arranged on the same surface, relative locations may be determined more conveniently according to a coupling strength, and errors are small

In one example, in the above construction method of the quantum chip, arranging the plurality of control signal transmission parts on the surface of the second substrate facing the first substrate includes: arrangement locations of the plurality of control signal transmission parts on the second substrate are determined according to the arrangement locations of the plurality of qubits, the coupler and the plurality of first controllers on the first substrate. In one example, locations of resonant cavities on the second substrate are arranged first according to the locations of the elements on the first substrate. Then, the locations of remaining components of the control signal transmission parts on the second substrate are determined. Specifically, sizes of the resonant cavities are determined by input initial parameters, overall lengths of the resonant cavities are determined according to values of frequencies of the resonant cavities, and then the resonant cavities are placed on the second substrate as needed. By adopting the above solution, the locations of the signal transmission parts on the second substrate are arranged according to the locations of the elements on the first substrate, so possible crosstalk between different elements and devices is reduced.

In one example, the above construction method of the quantum chip further includes: a simulation feature value is obtained by inputting the arrangement locations of the plurality of qubits, the coupler and the plurality of first controllers on the first substrate and the arrangement locations of the plurality of control signal transmission parts on the second substrate into a simulation system; and at least one of the arrangement locations is adjusted according to a difference between the simulation feature value and the target feature value. In one example, after obtaining all design sizes of the first substrate and the second substrate, in order to ensure that the designed quantum chip may better accord with the target feature value, all the design sizes are input into simulation software for simulation calculation. The simulation software may be finite element analysis software that is commonly used in the industry, which is not limited here. Then, a simulation result is compared to the target feature value, and under a condition of a difference between the two, fine adjustment is made to the sizes of the first substrate and the second substrate so that the sizes are closer to the target feature value. In conclusion, by using a verification manner, simulation verification is performed before the quantum chip is designed and is officially taped out, so as to increase a matching degree between feature parameters of the actually taped out chip and expected feature parameters of the chip.

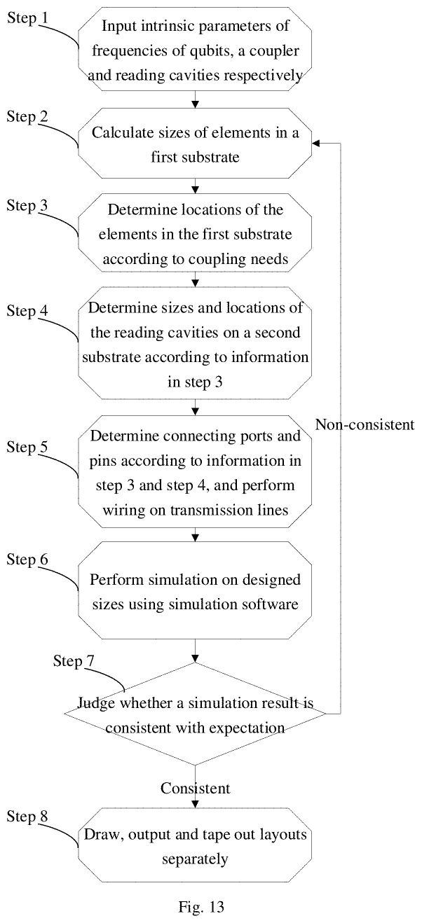

In one example, as shown in FIG. 13, steps for constructing the quantum chip may include the following steps: step 1, intrinsic parameters such as the frequencies of the qubits, the coupler and the reading cavities are input respectively; step 2, the sizes of the elements in the first substrate 100 are calculated; step 3, the locations of the elements in the first substrate 100 are determined according to coupling needs; step 4, the sizes and locations of the reading cavities on the second substrate 200 are determined according to information in step 3; step 5, connecting ports and pins are determined according to information in step 3 and step 4, and then wiring is performed based on transmission lines; step 6, the designed sizes are simulated by using the simulation software, and step 7, a subsequent step is performed if the simulation result is consistent with an expected target, or step 2 is performed; and step 8, layouts are separately drawn, output and taped out.

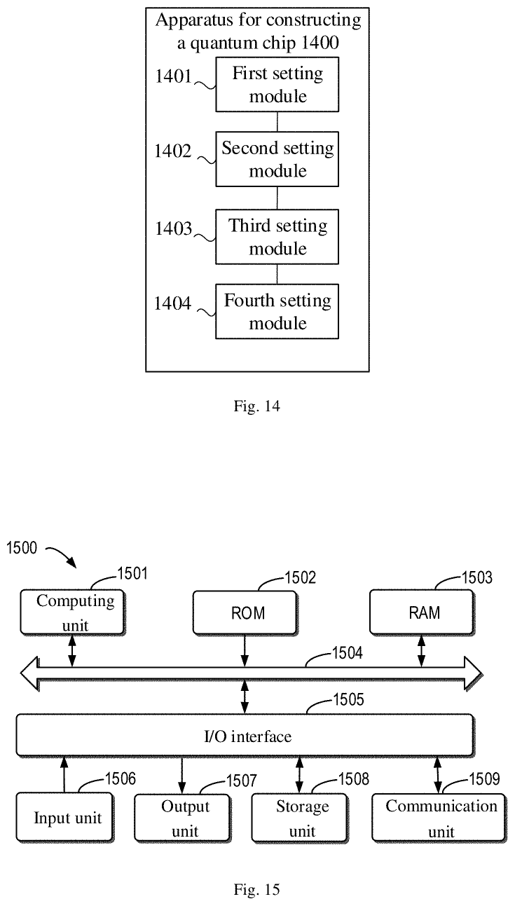

As shown in FIG. 14, an embodiment of the present disclosure provides a construction apparatus 1400 of a quantum chip. The apparatus includes:

a first setting module 1401, configured to arrange a first substrate and a second substrate opposite to each other;

a second setting module 1402, configured to arrange a plurality of sets of coupled qubits and first controllers on a surface of the first substrate facing the second substrate;

a third setting module 1403, configured to arrange a plurality of control signal transmission parts on a surface of the second substrate facing the first substrate; and

a fourth setting module 1404, configured to arrange a plurality of connecting pieces between the first substrate and the second substrate, so that the connecting pieces connect the plurality of first controllers to the plurality of control signal transmission parts in a one-to-one corresponding mode.

The above-mentioned construction apparatus further includes:

a fifth setting module, configured to arrange at least one coupler on the surface of the first substrate facing the second substrate, and cause the coupler to be located between the adjacent qubits.

In one example, the second setting module and the fifth setting module are configured to:

determine relative distances among the plurality of qubits, the coupler and the plurality of first controllers according to a target feature value; and determine arrangement locations of the plurality of qubits, the coupler and the plurality of first controllers on the first substrate according to sizes of the plurality of qubits, the coupler and the plurality of first controllers as well as the relative distances.

In one example, the third setting module in the above-mentioned apparatus is configured to:

determine arrangement locations of the plurality of control signal transmission parts on the second substrate according to the arrangement locations of the plurality of qubits, the coupler and the plurality of first controllers on the first substrate.

In one example, the above-mentioned apparatus further includes:

a simulation module, configured to obtain a simulation feature value by inputting the arrangement locations of the plurality of qubits, the coupler and the plurality of first controllers on the first substrate and the arrangement locations of the plurality of control signal transmission parts on the second substrate into a simulation system; and

an adjusting module, configured to adjust at least one of the arrangement locations according to a difference between the simulation feature value and the target feature value.

For functions of the modules in the apparatuses in the embodiments of the present disclosure, reference may be made to corresponding descriptions in the above method, which will not be repeated here.

In the technical solution of the present disclosure, collection, storage, use, processing, transmission, provision and disclosure of the user's personal information involved are all in compliance with stipulations of relevant laws and regulations, and do not violate public order and good customs.

According to embodiments of the present disclosure, the present disclosure further provides an electronic device, a readable storage medium and a computer program product.

FIG. 15 illustrates a block diagram of an electronic device 1500 for implementing a construction method of a quantum chip according to an embodiment of the present disclosure. The electronic device is intended to represent various forms of digital computers, such as laptop computers, desktop computers, workstations, personal digital assistants, servers, blade servers, mainframe computers, and other suitable computers. The electronic device may also represent various forms of mobile apparatuses, such as personal digital processors, cellular phones, smart phones, wearable devices, and other similar computing apparatuses. Components shown herein, their connections and relationships, and their functions are exemplary only, and are not intended to limit implementations of the present disclosure described and/or claimed herein.

As shown in FIG. 15, the device 1500 includes a computing unit 1501 that may perform various suitable actions and processes according to computer program instructions stored in a read only memory (ROM) 1502 or loaded into a random access memory (RAM) 1503 from a storage unit 1508. In the RAM 1503, various programs and data necessary for operation of the device 1500 may also be stored. The computing unit 1501, the ROM 1502, and the RAM 1503 are connected to one another through a bus 1504. An input/output (I/O) interface 1505 is also connected to the bus 1504.

A plurality of components in the device 1500 are connected to the I/O interface 1505, including: an input unit 1506, such as a keyboard, a mouse, etc.; an output unit 1507, such as various types of displays, speakers, etc.; the storage unit 1508, such as a disk, optical disc, etc.; and a communication unit 1509, such as a network card, a modem, a wireless communication transceiver, and the like. The communication unit 1509 allows the device 1500 to exchange information/data with other devices through a computer network such as Internet and/or various telecommunication networks.

The computing unit 1501 may be various general-purpose and/or special-purpose processing components with processing and computing capacities. Some examples of the computing unit 1501 include but are not limited to a central processing unit (CPU), a graphics processing unit (GPU), various special-purpose artificial intelligence (AI) computing chips, various computing units for running a machine learning model algorithm, a digital signal processor (DSP), and any appropriate processor, controller, microcontroller and the like. The computing unit 1501 performs various methods and processes described above, such as the construction method of the quantum chip. For example, in some embodiments, the construction method of the quantum chip may be implemented as a computer software program tangibly embodied on a machine-readable medium, such as the storage unit 1508. In some embodiments, a part or all of the computer programs may be loaded and/or installed on device 1500 via the ROM 1502 and/or the communication unit 1509. When the computer program is loaded into the RAM 1503 and is executed by the computing unit 1501, one or more steps of the construction method of the quantum chip described above may be performed. Alternatively, in other embodiments, the computing unit 1501 may be configured to execute the construction method of the quantum chip by any other suitable means (e.g., by means of firmware).

Various implementations of the systems and technologies described above in this paper may be implemented in a digital electronic circuit system, an integrated circuit system, a field programmable gate array (FPGA), an application specific integrated circuit (ASIC), an application specific standard part (ASSP), a system on chip (SOC), a complex programmable logic device (CPLD), computer hardware, firmware, software and/or their combinations. These various implementations may include: being implemented in one or more computer programs, wherein the one or more computer programs may be executed and/or interpreted on a programmable system including at least one programmable processor, and the programmable processor may be a special-purpose or general-purpose programmable processor, and may receive data and instructions from a storage system, at least one input apparatus, and at least one output apparatus, and transmit the data and the instructions to the storage system, the at least one input apparatus, and the at least one output apparatus.

Program codes for implementing the methods of the present disclosure may be written in any combination of one or more programming languages. These program codes may be provided to processors or controllers of a general-purpose computer, a special-purpose computer or other programmable data processing apparatuses, so that when executed by the processors or controllers, the program codes enable the functions/operations specified in the flow diagrams and/or block diagrams to be implemented. The program codes may be executed completely on a machine, partially on the machine, partially on the machine and partially on a remote machine as a separate software package, or completely on the remote machine or server.

In the context of the present disclosure, a machine-readable medium may be a tangible medium that may contain or store a program for use by or in connection with an instruction execution system, apparatus or device. The machine readable medium may be a machine readable signal medium or a machine readable storage medium. The machine readable medium may include but not limited to an electronic, magnetic, optical, electromagnetic, infrared, or semiconductor system, apparatus or device, or any suitable combination of the above contents. More specific examples of the machine readable storage medium will include electrical connections based on one or more lines, a portable computer disk, a hard disk, a random access memory (RAM), a read only memory (ROM), an erasable programmable read only memory (EPROM or flash memory), an optical fiber, a portable compact disk read only memory (CD-ROM), an optical storage device, a magnetic storage device, or any suitable combination of the above contents.

In order to provide interactions with users, the systems and techniques described herein may be implemented on a computer, and the computer has: a display apparatus for displaying information to the users (e.g., a CRT (cathode ray tube) or LCD (liquid crystal display) monitor); and a keyboard and a pointing device (e.g., a mouse or trackball), through which the users may provide input to the computer. Other types of apparatuses may further be used to provide interactions with users; for example, feedback provided to the users may be any form of sensory feedback (e.g., visual feedback, auditory feedback, or tactile feedback); an input from the users may be received in any form (including acoustic input, voice input or tactile input).

The systems and techniques described herein may be implemented in a computing system including background components (e.g., as a data server), or a computing system including middleware components (e.g., an application server) or a computing system including front-end components (e.g., a user computer with a graphical user interface or a web browser through which a user may interact with the implementations of the systems and technologies described herein), or a computing system including any combination of such background components, middleware components, or front-end components. The components of the system may be interconnected by digital data communication (e.g., a communication network) in any form or medium. Examples of the communication network include: a local area network (LAN), a wide area network (WAN) and the Internet.

A computer system may include a client and a server. The client and the server are generally away from each other and usually interact through a communication network. A relation between the client and the server is generated by running a computer program with a mutual client-server relation on a corresponding computer. The server may be a cloud server, or a server of a distributed system, or a server combined with a blockchain.

It should be understood that steps can be reranked, added or deleted by using various forms of flows shown above. For example, all the steps recorded in the present disclosure can be executed in parallel, or in sequence or in different orders. As long as a desired result of the technical solutions disclosed by the present disclosure can be realized, no limitation is made herein.

The above-mentioned specific embodiments do not constitute a limitation to the protection scope of the present disclosure. It should be understood by those skilled in the art that various modifications, combinations, sub-combinations and substitutions may occur depending on design requirements and other factors. Any modifications, equivalent replacements, and improvements made within the spirit and principles of the present disclosure should be included within the protection scope of the present disclosure.

1. A quantum chip, comprising:
a first substrate and a second substrate arranged opposite to each other, wherein a plurality of qubits and a plurality of first controllers are arranged on a surface of the first substrate facing the second substrate, each of the plurality of qubits is coupled with at least one of the plurality of first controllers, and a plurality of control signal transmission parts are arranged on a surface of the second substrate facing the first substrate; and
a plurality of connecting pieces, connected between the first substrate and the second substrate, and configured to connect the plurality of first controllers to the plurality of control signal transmission parts in a one-to-one corresponding mode.

2. The quantum chip according to claim 1, wherein each of the plurality first controllers comprises a coupling port and a connecting plate, wherein the coupling port is coupled to the qubit corresponding to a respective first controller of the plurality first controllers, and the connecting plate is connected to one of the plurality of connecting pieces corresponding to a respective first controller of the plurality first controllers.

3. The quantum chip according to claim 2, wherein each of the plurality of first controllers comprises at least one of a magnetic flux controller, a microwave controller and a reading controller.

4. The quantum chip according to claim 3, wherein each of the plurality of control signal transmission parts comprises at least one of a magnetic flux control signal transmission part, a microwave control signal transmission part and a reading control signal transmission part.

5. The quantum chip according to claim 2, wherein each of the plurality of first controllers comprises a magnetic flux controller, and the magnetic flux controller further comprises:
a magnetic flux control circuit, arranged between the coupling port and the connecting plate, and configured to adjust a frequency of the qubit corresponding to the magnetic flux controller.

6. The quantum chip according to claim 2, wherein each of the plurality of first controllers comprises a reading controller, and the coupling port of the reading controller comprises an interdigital capacitor.

7. The quantum chip according to claim 6, wherein each of the plurality of control signal transmission parts comprises a reading control signal transmission part corresponding to the reading controller, and the reading control signal transmission part comprises a reading cavity and a reading signal line, wherein the reading cavity is connected to the connecting plate of the reading controller.

8. The quantum chip according to claim 1, further comprising:
at least one coupler, arranged on the surface of the first substrate facing the second substrate, and located between the adjacent qubits; and
at least one second controller, arranged in one-to-one correspondence to the at least one coupler, and configured to adjust a frequency of the corresponding coupler.

9. The quantum chip according to claim 8, wherein the at least one coupler comprises a rectangular capacitor and a Josephson junction arranged on the rectangular capacitor.

10. A method for constructing a quantum chip, comprising:
arranging a first substrate and a second substrate opposite to each other;
arranging a plurality of qubits and a plurality of first controllers on a surface of the first substrate facing the second substrate, each of the plurality of qubits is coupled with at least one of the plurality of first controllers;
arranging a plurality of control signal transmission parts on a surface of the second substrate facing the first substrate; and
arranging a plurality of connecting pieces between the first substrate and the second substrate, such that the connecting pieces connect the plurality of first controllers to the plurality of control signal transmission parts in a one-to-one corresponding mode.

11. The method according to claim 10, further comprising:
arranging at least one coupler on the surface of the first substrate facing the second substrate and located between the adjacent qubits of the plurality qubits.

12. The method according to claim 11, wherein arranging the plurality of qubits, the plurality of first controllers and the at least one coupler on the surface of the first substrate facing the second substrate comprises:
determining relative distances among the plurality of qubits, the at least one coupler and the plurality of first controllers according to a target feature value; and
determining arrangement locations of the plurality of qubits, the at least one coupler and the plurality of first controllers on the first substrate according to sizes of the plurality of qubits, the at least one coupler and the plurality of first controllers, and the relative distances.

13. The method according to claim 12, wherein arranging the plurality of control signal transmission parts on the surface of the second substrate facing the first substrate comprises:
determining arrangement locations of the plurality of control signal transmission parts on the second substrate according to the arrangement locations of the plurality of qubits, the at least one coupler and the plurality of first controllers on the first substrate.

14. The method according to claim 13, further comprising:
obtaining a simulation feature value by inputting the arrangement locations of the plurality of qubits, the at least one coupler and the plurality of first controllers on the first substrate and the arrangement locations of the plurality of control signal transmission parts on the second substrate into a simulation system; and
adjusting at least one of the arrangement locations according to a difference between the simulation feature value and the target feature value.

15. An electronic device, comprising:
a memory storing one or more programs configured to be executed by one or more processors, the one or more programs including instructions for causing the electronic device to perform operations comprising:
arranging a first substrate and a second substrate opposite to each other;
arranging a plurality of qubits and a plurality of first controllers on a surface of the first substrate facing the second substrate, each of the plurality of qubits is coupled with at least one of the plurality of first controllers;
arranging a plurality of control signal transmission parts on a surface of the second substrate facing the first substrate; and
arranging a plurality of connecting pieces between the first substrate and the second substrate, such that the connecting pieces connect the plurality of first controllers to the plurality of control signal transmission parts in a one-to-one corresponding mode.

16. The electronic device according to claim 15, the operations further comprising:
arranging at least one coupler on the surface of the first substrate facing the second substrate and located between the adjacent qubits of the plurality qubits.

17. The electronic device according to claim 16, wherein arranging the plurality of qubits, the plurality of first controllers and the at least one coupler on the surface of the first substrate facing the second substrate comprises:
determining relative distances among the plurality of qubits, the at least one coupler and the plurality of first controllers according to a target feature value; and
determining arrangement locations of the plurality of qubits, the at least one coupler and the plurality of first controllers on the first substrate according to sizes of the plurality of qubits, the at least one coupler and the plurality of first controllers, and the relative distances.

18. The electronic device according to claim 17, wherein arranging the plurality of control signal transmission parts on the surface of the second substrate facing the first substrate comprises:
determining arrangement locations of the plurality of control signal transmission parts on the second substrate according to the arrangement locations of the plurality of qubits, the at least one coupler and the plurality of first controllers on the first substrate.

19. The electronic device according to claim 18, the operations further comprising:
obtaining a simulation feature value by inputting the arrangement locations of the plurality of qubits, the at least one coupler and the plurality of first controllers on the first substrate and the arrangement locations of the plurality of control signal transmission parts on the second substrate into a simulation system; and
adjusting at least one of the arrangement locations according to a difference between the simulation feature value and the target feature value.
